(19) United States
(12) Patent Application Publication
(10) Pub. No.: US 2011/0292675 A1
(43) Pub. Date: Dec. 1, 2011

(54) LED DEVICE HAVING LIGHT GUIDE ARRAY WITH CURVED SURFACE

(76) Inventor: Liang-Shu Wang, Taipei (TW)

(21) Appl. No.: 13/084,520

(22) Filed: Apr. 11, 2011

(30) Foreign Application Priority Data
May 25, 2010 (TW) 099116628

(51) Int. Cl. H01L 33/02

(52) U.S. Cl. 362/555

(57) ABSTRACT

In an LED device, a light guide array is disposed between a planar LED array light source and a curved housing. A first surface of the light guide array is a plane evenly distanced from the LED array and a second surface of the light guide array is a curved surface evenly distanced from the curved housing. A plurality of guiding channels, either one-to-one or one-to-many to the LED, are aligning along each light axis of the LED in the light guide array, whose reflective surface allows the lights emitted by each LED to reflect thereon and emit from the second surface and simulate a curved light source having substantially the same shape as the curved housing.

### BACKGROUND OF THE INVENTION

1. Field of the Invention

The invention relates to an LED device, and more particularly, to an LED device having light guide array with curved surface for simulation of curved light source.

2. Description of the Prior Art

Light emitting diode (LED) has characteristic of low power consumption and high service life. Maturity of the technology of LED has gained many applications in illumination and indication area for LED devices. Illumination or indication with specific area of devices usually requires the LEDs to be arranged as an array on a circuit board, or a hard circuit board to be more specifically, that extensively limits the LED array to planar applications only. For those increasingly emerging situations of applying LED array to a curved shape device, such as indicative display area of a robot, traffic signals, curved electronic board, the planar distributed LED array will be easily found to be located at a planar surface, under any indirect viewing angle to the LED array. This simply damages the original shape design.

Presently for some curved display boards with large dimension, multiple circuit boards, each having multiple LED array, are jointed and combined together to simulate the effect of curved surface. The combination of multiple circuit boards also brings about the increase of cost, the complexity of putting together all the circuit boards, and also lower the reliability compared with applications with single circuit board.

### SUMMARY OF THE INVENTION

A light guide array corresponding to a curved housing is disposed between the curved housing and a circuit substrate, allowing an LED device for simulating a curved light source and giving more vivid experience of the product.

Embodiments of the invention provide an LED device having light guide array with curved surface. The LED device includes a substrate, a light guide array, and a curved housing. The substrate includes a plurality of light emitting diodes (LED). Each LED emits lights along a light axis. The light guide array includes a plurality of guiding channels, a first surface, and a second surface. The plurality of guiding channels penetrates the first surface and the second surface and has a same orientation as the light axis. The lights emitted by the plurality of LEDs enter the plurality of guiding channels from the first surface and emit out of the second surface after reflected in the plurality of guiding channels. The light guide array is disposed between the substrate and the curved housing. The first surface is located at a side of the light guide array facing the substrate, the second surface is located at a side of the light guide array facing the curved housing, the first surface and the substrate are planes, and the second surface and the curved housing are curved surfaces.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram of an embodiment showing an LED device having curved light guide array.

FIG. 2 is a front view of the light guide array of the embodiment.

FIG. 3 is a side view of the light guide array of the embodiment.

FIG. 4 is a side cross-sectional view of part of the LED device.

### DETAILED DESCRIPTION

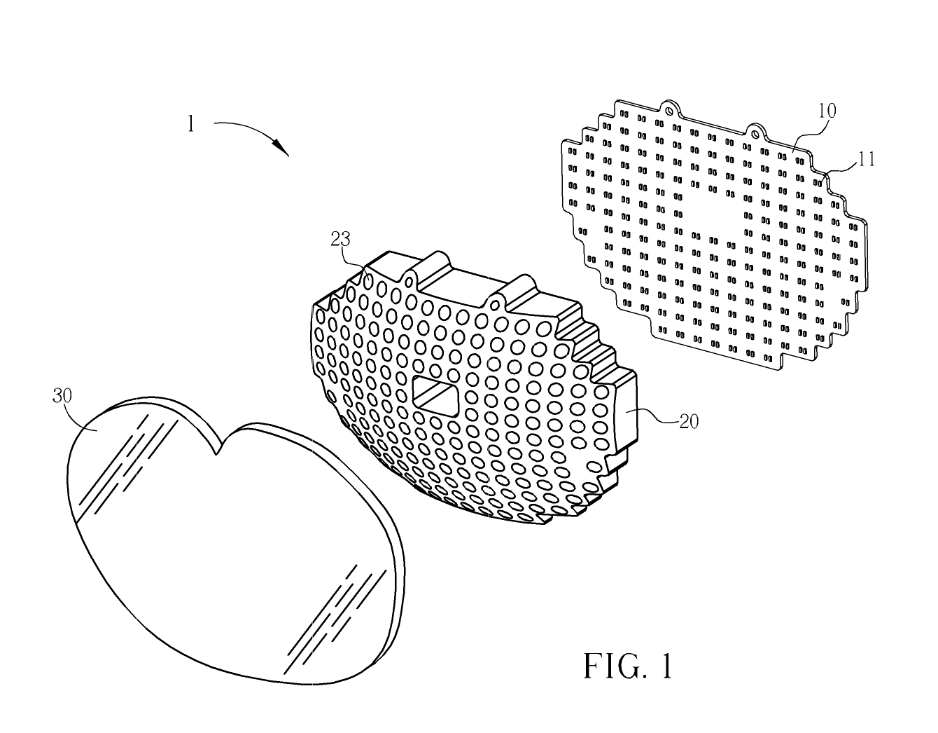

Please refer to FIG. 1, which is a schematic diagram of an embodiment showing an LED device 1 having curved light guide array. The LED device 1 includes a planar substrate 10, a light guide array 20, and a curved housing 30. The planar substrate 10 is a hard circuit board having a plurality of light emitting diodes 11 thereon. In this embodiment, the light emitting diodes (LEDs) 11 are arranged as an array on the substrate 10 and are used for providing a large area planar light source. The curved housing 30 has curved surface to correspond to any device to which the LEDs 11 is applied. The curved housing 30 can be made of translucent acryl, plastic, or glass. The light guide array 20 is disposed between the substrate 10 and the curved housing 30. In this embodiment, the light guide array 20 can transform the planar light source generated by the LEDs 11 array into a curved light source corresponding to the curved housing 30.

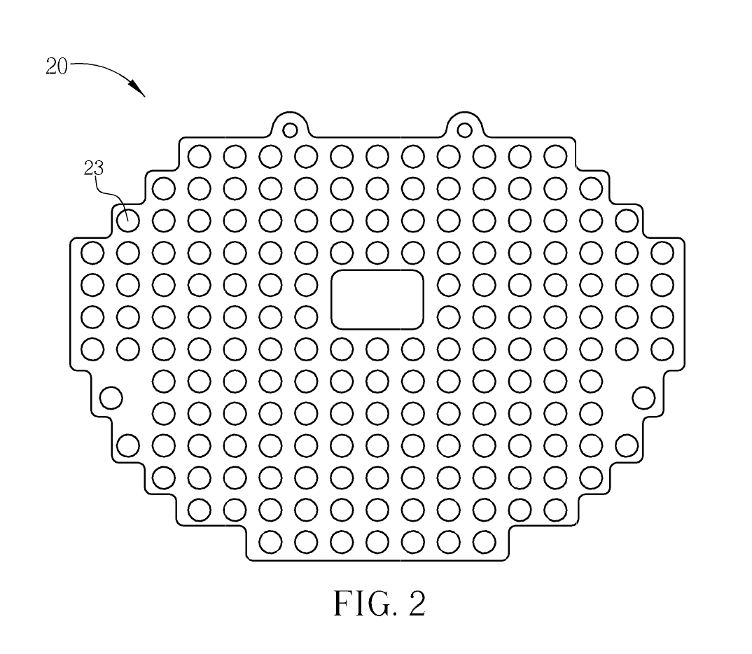

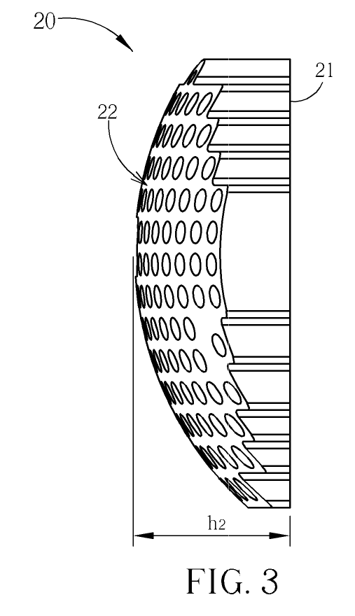

Please refer to FIG. 2 and FIG. 3. FIG. 2 is a front view of the light guide array 20 of the embodiment, and FIG. 3 is a side view of the light guide array 20. As shown in the figures, the light guide array 20 includes a plurality of guiding channels 23, each penetrating a first surface 21 and a second surface 22 of the light guide array 20. In the LED device 1, the number of the guiding channel 23 can be the same as the number of the LEDs 11 on the substrate 10, with one-to-one relations, allowing the light emitted by each LED 11 for entering each corresponding guiding channel 23 from the first surface 21 and emitting out of the second surface 22. It is also possible for the guiding channels 23 to correspond to the LEDs 11 in a one-to-many way, which means lights emitted from multiple LEDs 11 enter a shared corresponding guiding channel 23 from the first surface 21 and emit out of the second surface 22.

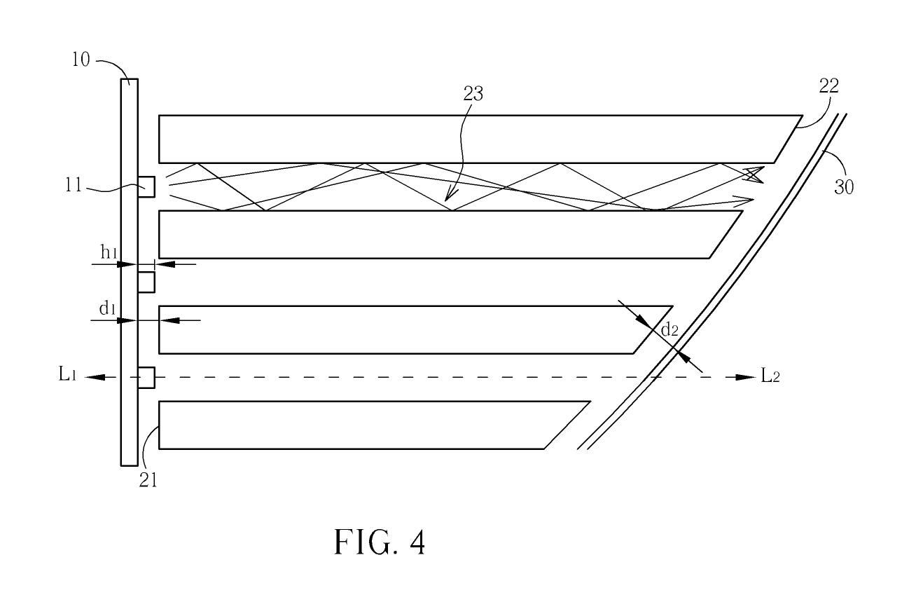

Please refer to FIG. 4, which is a side cross-sectional view of the LED device 1. Given the arranged LEDs 11 array and the substrate 10 as a plane, the first surface 21, which is located at a side of the light guide array 20 facing the substrate 10, is also a plane having a plurality of penetrating openings of the guiding channels 23 to effectively receive lights emitted by the LEDs 11 along each light axis, the L₁L₂ axis as shown in FIG. 4. The first surface 21 is evenly distanced from the substrate 10 by a first distance d₁. Considering the receiving rate of lights emitted by the LEDs 11, the first distance d₁ is preferably no greater than seven times a first length h₁ of the LEDs 11, where the first length h₁ stands for the dimension of each LED 11 along each light axis. Hence, the light guide array 20 can effectively receive lights emitted by the LEDs 11 array with a relatively close configuration of the first surface 21 to the substrate 10.

In the light guide array 20, each guiding channel 23 has the same orientation as the light axis of each corresponding one or more LEDs 11. The surface of each guiding channel 23 can be light reflective mirror surface. The light guide array 20 can be made from a plastic piece having such multiple channels processed with electroplate or paint spraying on the inner surfaces of the channels. Through the process, such plastic piece can be processed into the light guide array 20 with many guiding channels 23 with reflective mirror surfaces. As the lights emitted by the LEDs 11 along the light axis L₁L₂ enter into each penetrating opening of the guiding channels 23 at the first surface 21, the lights are reflected on the mirror surfaces inside each guiding channel 23 all the way to the penetrating opening of each guiding channel 23 at the second surface 22. With each guiding channel 23 of the light guide array 20, the characteristic of light source of the LEDs 11 array on the substrate 10, especially for the application of using the LEDs array as indicating source, can be maintained or have similar performance when the lights emit out of the second surface 22. The processed inner surfaces of each guiding channel 23 also ensure that the lights pass through the corresponding guiding channels 23 only, not interfering with lights in another guiding channels 23.

The curved housing 30 of the LED device 1 has curved surface as final presentation. The second surface 22 of light guide array 20 facing the curved housing 30 also has curved surface to have match orientation with the curved housing 30. The second surface 22 is distanced from the curved housing 30 evenly by a second distance d₂, which is preferably no greater than one third a second length h₂ of a longest guiding channel 23 of the light guide array 20. The second length h₂ also stands for the largest thickness of the light guide array 20 as shown in FIG. 3. Such feature can ensure the presented effect of the lights emitted from each guiding channel 23 and out of the curved housing 30. Hence, the light guide array 20 and the curved housing 30 can effectively simulate a curved array of light source with a relatively close configuration of the curved housing 30 to the second surface 22.

In the above figures, the shape of the second surface 22 of the light guide array 20 is drawn as shown to demonstrate how the light guide array 20 corresponds to the shape of the curved housing 30. However, the shape of the light guide array 20 and the curved housing 30 of the LED device 1 should not be limited by the embodiment shown in the figures. Any practice of LED device that has a light guide array disposed between a planar LED array light source and a curved housing and the light guide array has corresponding guiding channels and a first surface corresponding to the planar LED array light source, a second surface corresponding to the curved housing should also be placed within the scope of the invention.

Those skilled in the art will readily observe that numerous modifications and alterations of the device and method may be made while retaining the teachings of the invention.

What is claimed is:

1. An LED device having light guide array with curved surface, comprising:
a substrate, comprising a plurality of light emitting diodes (LED), each LED emitting lights along a light axis;
a light guide array, comprising a plurality of guiding channels, a first surface, and a second surface, the plurality of guiding channels penetrating the first surface and the second surface and having a same orientation as the light axis, the lights emitted by the plurality of LEDs entering the plurality of guiding channels from the first surface and emitting out of the second surface after reflected in the plurality of guiding channels; and
a curved housing, the light guide array disposed between the substrate and the curved housing;
wherein the first surface is located at a side of the light guide array facing the substrate, the second surface is located at a side of the light guide array facing the curved housing, the first surface and the substrate are planes, and the second surface and the curved housing are curved surfaces.

2. The LED device of claim 1, wherein the plurality of guiding channels correspond one-to-one to each of the LEDs at the first surface.

3. The LED device of claim 1, wherein the plurality of guiding channels correspond one-to-many to each of the LEDs at the first surface.

4. The LED device of claim 1, wherein the surfaces of the plurality of guiding channels are reflective mirror surfaces.

5. The LED device of claim 4, wherein the light guide array are plastic and the surfaces of the plurality of guiding channels are electroplate or paint spraying mirror surfaces.

6. The LED device of claim 1, wherein the first surface is a plane evenly distanced from the substrate, and the second surface is a curved surface evenly distanced from the curved housing.

7. The LED device of claim 6, wherein the first surface is distanced from the substrate by a first distance, the plurality of LEDs has the dimension of a first length along the light axis, and the first distance is no greater than seven times the first length of the LEDs.

8. The LED device of claim 6, wherein the second surface is distanced from the curved housing by a second distance, a longest guiding channel of the light guide array has the dimension of a second length, and the second distance is no greater than one third the second length of the longest guiding channel.

9. The LED device of claim 1, wherein the first surface is distanced from the substrate by a first distance, the plurality of LEDs has the dimension of a first length along the light axis, and the first distance is no greater than seven times the first length of the LEDs.

10. The LED device of claim 1, wherein the second surface is distanced from the curved housing by a second distance, a longest guiding channel of the light guide array has the dimension of a second length, and the second distance is no greater than one third the second length of the longest guiding channel.
